(19) United States
(12) Patent Application Publication
(10) Pub. No.: US 2024/0386944 A1
(43) Pub. Date: Nov. 21, 2024

(54) MEMORY DEVICE USING SEMICONDUCTOR ELEMENTS

(71) Applicant: Unisantis Electronics Singapore Pte. Ltd., Singapore (SG)

(72) Inventors: Koji SAKUI, Tokyo (JP); Masakazu KAKUMU, Tokyo (JP); Nozomu HARADA, Tokyo (JP)

(21) Appl. No.: 18/662,248

(22) Filed: May 13, 2024

(30) Foreign Application Priority Data
May 17, 2023 (WO) PCT/JP2023/018435

(51) Int. Cl. G11C 11/4096; G11C 11/404; H01L 27/092; H01L 29/78; H03K 19/20

(52) U.S. Cl. CPC G11C 11/4096; G11C 11/404; H01L 27/0928; H03K 19/20; H01L 29/7827

(57) ABSTRACT

A semiconductor device includes a substrate, and an N-type MOS transistor and a P-type MOS transistor on the substrate. In the semiconductor device, during an erase operation, the hole group in a P-type semiconductor layer, which is the body of the N-type MOS transistor, and the electron group in an N-type semiconductor layer, which is the body of the P-type MOS transistor, are decreased; and during a write operation, the hole group in the P-type semiconductor layer of the N-type MOS transistor and the electron group in the N-type semiconductor layer of the P-type MOS transistor are increased. The N-type MOS transistor and the P-type MOS transistor forms a logic circuit configured to provide an output in a high impedance state (Hi-Z state) during the erase operation and to provide an output of a logic “1” or a logic “0” in a low impedance state during the write operation.

### CROSS REFERENCES TO RELATED APPLICATIONS

This application claims priority to PCT/JP2023/018435, filed May 17, 2023, the entire content of which is incorporated herein by reference.

### BACKGROUND OF THE INVENTION

### 1. Field of the Invention

The present invention relates to a memory device using semiconductor elements.

### 2. Description of the Related Art

In recent years, the development of Large-Scale Integration (LSI) technology has aimed at achieving greater integration, enhanced performance, reduced power consumption, and improved functionality in memory elements.

In standard planar MOS transistors, the channel extends horizontally along the upper surface of the semiconductor substrate. In contrast, the channel in surrounding gate transistors (SGTs) extends vertically relative to the upper surface of the semiconductor substrate (see, for example, Japanese Patent Application No. 3-171768, and Hiroshi Takato, Kazumasa Sunouchi, Naoko Okabe, Akihiro Nitayama, Katsuhiko Hieda, Fumio Horiguchi, and Fujio Masuoka: IEEE Transaction on Electron Devices, Vol. 38, No. 3, pp. 573-578 (1991)). For this reason, SGTs facilitate a higher density of semiconductor devices compared to planar MOS transistors. By using SGTs as select transistors, enhanced integration is achieved in technologies such as dynamic random access memory (DRAM), which incorporates connected capacitors (see, for example, H. Chung, H. Kim, H. Kim, K. Kim, S. Kim, K. W. Song, J. Kim, Y. C. Oh, Y. Hwang, H. Hong, G. Jin, and C. Chung: “4F2 DRAM Cell with Vertical Pillar Transistor (VPT),” 2011 Proceeding of the European Solid-State Device Research Conference, (2011)), phase change memory (PCM), which incorporates connected variable resistance elements (see, for example, H. S. Philip Wong, S. Raoux, S. Kim, Jiale Liang, J. R. Reifenberg, B. Rajendran, M. Asheghi and K. E. Goodson: “Phase Change Memory,” Proceeding of IEEE, Vol. 98, No 12, December, pp2b012b27 (2010)), resistive random access memory (RRAM) (see, for example, K. Tsunoda, K. Kinoshita, H. Noshiro, Y. Yamazaki, T. Iizuka, Y. Ito, A. Takahashi, A. Okano, Y. Sato, T. Fukano, M. Aoki, and Y. Sugiyama: “Low Power and high Speed Switching of Ti-doped NiO ReRAM under the Unipolar Voltage Source of less than 3V,” IEDM (2007)), and magneto-resistive random access memory (MRAM), which alters resistance by changing the direction of magnetic spins using electric current (see, for example, W. Kang, L. Zhang, J. Klein, Y. Zhang, D. Ravelosona, and W. Zhao: “Reconfigurable Codesign of STT-MRAM Under Process Variations in Deeply Scaled Technology,” IEEE Transaction on Electron Devices, pp. 1-9 (2015)). Examples of these technologies also include DRAM memory cells composed of a single MOS transistor without incorporating a capacitor (see M. G. Ertosun, K. Lim, C. Park, J. Oh, P. Kirsch, and K. C. Saraswat: “Novel Capacitorless Single-Transistor Charge-Trap DRAM (1T CT DRAM) Utilizing Electron,” IEEE Electron Device Letter, Vol. 31, No. 5, pp. 405-407 (2010)) and DRAM memory cells having a carrier groove and two gate electrodes (see Md. Hasan Raza Ansari, Nupur Navlakha, Jae Yoon Lee, Seongjae Cho, “Double-Gate Junctionless 1T DRAM With Physical Barriers for Retention Improvement,” IEEE Trans, on Electron Devices vol. 67, pp. 1471-1479 (2020)). However, a problem arises in DRAMs without capacitors: achieving adequate voltage margins become challenging because these voltage margins significantly depend on the coupling of gate electrodes from the word line in the floating body. Furthermore, when complete depletion occurs in the substrate, the adverse effects intensify. For example, some memory devices are composed of MOS transistors without incorporating a capacitor (see US2023/0077140 A1 and US2023/0108227 A1). The following documents are also examples of related art: US2008/0137394 A1; US2003/0111681 A1; Japanese Patent No. 7057032; Takashi Ohasawa and Takeshi Hamamoto, “Floating Body Cell—a Novel Body Capacitorless DRAM Cell,” Pan Stanford Publishing (2011); H. Jiang, N. Xu, B. Chen, L. Zeng1, Y. He, G. Du, X. Liu and X. Zhang: “Experimental investigation of self-heating effect (SHE) in multiple-fin SOI FinFETs,” Semicond. Sci. Technol. 29 (2014) 115021 (7pp); J. Y. Song, W. Y. Choi, J. H. Park, J. D. Lee, and B-G. Park: “Design Optimization of Gate-All-Around (GAA) MOSFETS,” IEEE Trans. Electron Devices, vol. 5, no. 3, pp. 186-191, May 2006; N. Loubet, et al.: “Stacked Nanosheet Gate-All-Around Transistor to Enable Scaling Beyond FinFET,” 2017 IEEE Symposium on VLSI Technology Digest of Technical Papers, T17-5, T230-T231, June 2017. The present application relates to a semiconductor device that is realized by using a memory device composed of MOS transistors without incorporating a capacitor. The semiconductor device is designed to facilitate the implementation of field programmable gate arrays (FPGAs) using a logic circuit in the semiconductor device, constituted by N-type and P-type MOS transistors.

### SUMMARY OF THE INVENTION

Although field programmable gate arrays (FPGAs) are incorporated to implement variable logic circuits, a high power consumption issue arises because many semiconductor devices use static random access memory (SRAM). Furthermore, the practical application of reconfigurable logic circuits, which remains reconfigurable during operation of the semiconductor devices, is difficult.

To address the problems described above, according to a first aspect of the invention, a semiconductor device includes a substrate, and an N-type MOS transistor and a P-type MOS transistor that are disposed on the substrate. The N-type MOS transistor includes an N-type MOS transistor body, an N-type gate conductor layer, and an N-type insulating layer. The P-type MOS transistor includes a P-type MOS transistor body, a P-type gate conductor layer, and a P-type insulating layer. The N-type MOS transistor body is constituted by a first P-type body semiconductor layer configured to accumulate a hole group and a second P-type body semiconductor layer connected to the first P-type body semiconductor layer and configured to control a positive threshold voltage of the N-type MOS transistor based on concentration of the hole group in the first P-type body semiconductor layer. The P-type MOS transistor body is constituted by a first N-type body semiconductor layer configured to accumulate an electron group and a second N-type body semiconductor layer connected to the first N-type body semiconductor layer and configured to control a negative threshold voltage of the P-type MOS transistor based on concentration of the electron group in the first N-type body semiconductor layer. The N-type gate conductor layer and the P-type gate conductor layer are composed of the same material. The N-type insulating layer is disposed between the second P-type body semiconductor layer and the N-type gate conductor layer, and the P-type insulating layer is disposed between the second N-type body semiconductor layer and the P-type gate conductor layer. The N-type insulating layer and the P-type insulating layer are composed of the same material. The semiconductor device is configured to perform an erase operation by increasing the positive threshold voltage of the N-type MOS transistor and decreasing the negative threshold voltage of the P-type MOS transistor. The increasing the positive threshold voltage of the N-type MOS transistor is achieved by decreasing the hole group in the first P-type body semiconductor layer and the hole group in the second P-type body semiconductor layer within the N-type MOS transistor. The decreasing the negative threshold voltage of the P-type MOS transistor is achieved by decreasing the electron group in the first N-type body semiconductor layer and the electron group in the second N-type body semiconductor layer within the P-type MOS transistor. The semiconductor device is configured to perform a write operation by decreasing the positive threshold voltage of the N-type MOS transistor and increasing the negative threshold voltage of the P-type MOS transistor. The decreasing the positive threshold voltage of the N-type MOS transistor is achieved by increasing the hole group in the first P-type body semiconductor layer and the hole group in the second P-type body semiconductor layer within the N-type MOS transistor. The increasing the negative threshold voltage of the P-type MOS transistor is achieved by increasing the electron group in the first N-type body semiconductor layer and the electron group in the second N-type body semiconductor layer within the P-type MOS transistor. The N-type MOS transistor and the P-type MOS transistor forms a logic circuit configured to provide an output in a high impedance state (Hi-Z state) during the erase operation and to provide an output of a logic “1” or a logic “0” in a low impedance state during the write operation.

According to a second aspect of the invention, with respect to the first aspect of the invention, during the erase operation, in the N-type MOS transistor, a portion of the hole groups remaining in the first P-type body semiconductor layer and the second P-type body semiconductor layer is removed by recoupling the portion of the hole groups with an electron group in at least one first N-type impurity layer that is disposed in contact with the first P-type body semiconductor layer or the second P-type body semiconductor layer. During the erase operation, in the P-type MOS transistor, a portion of the electron groups remaining in the first N-type body semiconductor layer and the second N-type body semiconductor layer is removed by recoupling the portion of the electron groups with a hole group in at least one first P-type impurity layer that is disposed in contact with the first N-type body semiconductor layer or the second N-type body semiconductor layer. During the write operation, in the N-type MOS transistor, the hole group in the first P-type body semiconductor layer and the hole group in the second P-type body semiconductor layer are formed through an impact ionization phenomenon caused by a current flowing between a second N-type impurity layer and a third N-type impurity layer that are disposed in contact with the first P-type body semiconductor layer or the second P-type body semiconductor layer, or the hole group in the first P-type body semiconductor layer and the hole group in the second P-type body semiconductor layer are formed by a gate-induced drain leak current. The semiconductor device is configured to perform an operation that causes a portion or all of the hole groups in the first P-type body semiconductor layer and the second P-type body semiconductor layer to remain in the first P-type body semiconductor layer and the second P-type body semiconductor layer. During the write operation, in the P-type MOS transistor, the electron group in the first N-type body semiconductor layer and the electron group in the second N-type body semiconductor layer are formed through an impact ionization phenomenon caused by a current flowing between a second P-type impurity layer and a third P-type impurity layer that are disposed in contact with the first N-type body semiconductor layer or the second N-type body semiconductor layer, or the electron group in the first N-type body semiconductor layer and the electron group in the second N-type body semiconductor layer are formed by a gate-induced drain leak current. The semiconductor device is configured to perform an operation that causes a portion or all of the electron groups in the first N-type body semiconductor layer and the second N-type body semiconductor layer to remain in the first N-type body semiconductor layer and the second N-type body semiconductor layer.

According to a third aspect of the invention, with respect to the second aspect of the invention, the second N-type impurity layer is connected to an N-type source line in the N-type MOS transistor, and the third N-type impurity layer is connected to an N-type drain line in the N-type MOS transistor.

According to a fourth aspect of the invention, with respect to the second aspect of the invention, the second P-type impurity layer is connected to a P-type source line in the P-type MOS transistor, and the third P-type impurity layer is connected to a P-type drain line in the P-type MOS transistor.

According to a fifth aspect of the invention, with respect to the first aspect of the invention, the logic circuit is an inverter circuit, a NAND gate circuit, or a NOR gate circuit.

According to a sixth aspect of the invention, with respect to the first aspect of the invention, the first N-type body semiconductor layer and the second N-type body semiconductor layer are provided as an N-type well in a P-type semiconductor layer.

According to a seventh aspect of the invention, with respect to the first aspect of the invention, the first P-type body semiconductor layer and the second P-type body semiconductor layer are provided as a P-type well in an N-type semiconductor layer.

According to an eighth aspect of the invention, with respect to the first aspect of the invention, each of the positive threshold voltage of the N-type MOS transistor and an absolute value of the negative threshold voltage of the P-type MOS transistor is smaller than a difference between a supply voltage to the logic circuit and a ground voltage in the write operation and greater than the difference between the supply voltage to the logic circuit and the ground voltage in the erase operation.

According to a ninth aspect of the invention, with respect to the first aspect of the invention, the hole groups in the first P-type body semiconductor layer and the second P-type body semiconductor layer are moved by a diffusion current.

According to a tenth aspect of the invention, with respect to the first aspect of the invention, the electron groups in the first N-type body semiconductor layer and the second N-type body semiconductor layer are moved by a diffusion current.

### BRIEF DESCRIPTION OF THE DRAWINGS

FIGS. 1A and 1B provide a sectional view and a plan view of the structure of a semiconductor device constituted by N-type and P-type MOS transistors according to a first embodiment;

FIG. 2 illustrates a write operation of the semiconductor device in FIG. 1;

FIG. 3 illustrates the carrier movement and drain-to-source current immediately after the write operation of the semiconductor device in FIG. 1;

FIG. 4 illustrates an erase operation of the semiconductor device in FIG. 1;

FIG. 5 illustrates the carrier movement and drain-to-source current immediately after the erase operation of the semiconductor device in FIG. 1;

FIGS. 6A, 6B, 6C, and 6D illustrate an inverter circuit constituted by the N-type and P-type MOS transistors according to the first embodiment;

FIG. 7 is a sectional view of the structure of the inverter circuit constituted by the N-type and P-type MOS transistors according to the first embodiment;

FIGS. 8A, 8B, 8C, and 8D illustrate a two-input NAND gate circuit constituted by the N-type and P-type MOS transistors according to the first embodiment; and

FIGS. 9A, 9B, 9C, and 9D illustrate a two-input NOR gate circuit constituted by the N-type and P-type MOS transistors according to the first embodiment.

### DESCRIPTION OF THE PREFERRED EMBODIMENTS

Hereinafter, the structure and drive method of a semiconductor device according to an embodiment of the present invention and the behavior of accumulated carriers in the semiconductor device will be described with reference to the accompanying drawings.

### First Embodiment

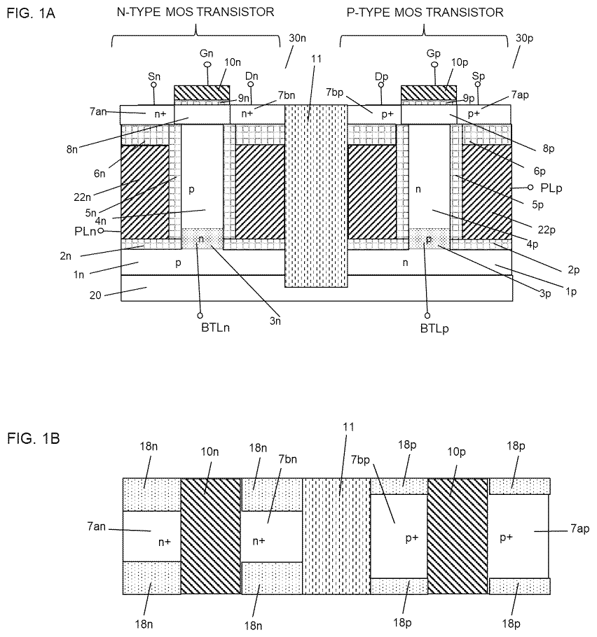

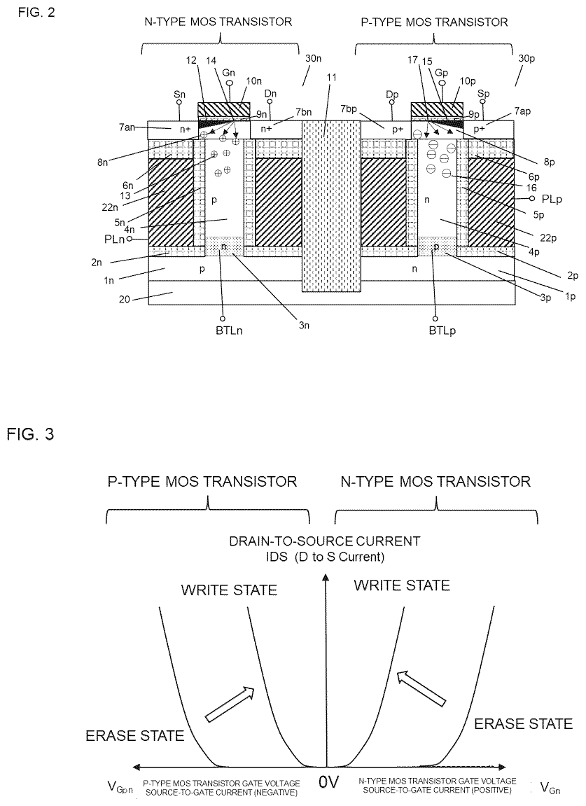

The structure and operating mechanisms of N-type and P-type MOS transistors according to a first embodiment of the present invention will be described with reference to FIGS. 1A, 1B, 2, and 3. Referring to FIGS. 1A and 1B, the structures of N-type and P-type MOS transistors that constitute a semiconductor device according to the present embodiment will be individually described. Referring to FIG. 2, the mechanisms of an erase operation and a write operation and the carrier behavior of the N-type and P-type MOS transistors will be described. Referring to FIG. 3, the current-voltage characteristics of the N-type and P-type MOS transistors will be described.

FIGS. 1A and 1B illustrate a sectional structure of an N-type MOS transistor 30n (an example of an “N-type MOS transistor” in the claims) and a P-type MOS transistor 30p (an example of a “P-type MOS transistor” in the claims) according to the first embodiment of the invention. FIG. 1A provides a sectional view, and FIG. 1B provides a plan view. First, the structure of the N-type MOS transistor will be described. A first P-type semiconductor layer 1n (hereinafter also referred to as “p layer 1n”) is disposed on a substrate 20 (an example of a “substrate” in the claims). The first P-type semiconductor layer 1n is composed of silicon containing acceptor impurities and exhibits p-type conductivity. A columnar first N-type impurity layer 3n (hereinafter also referred to as “n layer 3n”) containing donor impurities extends vertically from the surface of the p layer 1n. A columnar first P-type body semiconductor layer 4n (an example of a “first P-type body semiconductor layer” in the claims and hereinafter also referred to as “p layer 4n”) containing acceptor impurities is disposed on the first N-type impurity layer 3n. A first N-type insulating layer 2n covers the portion of the p layer 1n that corresponds to the region outside the n layer 3n. A first N-type gate insulating layer 5n covers a portion of the p layer 4n. A first N-type gate conductor layer 22n is disposed in contact with the first N-type insulating layer 2n and the first N-type gate insulating layer 5n. A second N-type insulating layer 6n is disposed in contact with the first N-type gate insulating layer 5n and the first N-type gate conductor layer 22n. A second P-type body semiconductor layer 8n (an example of a “second P-type body semiconductor layer” in the claims and hereinafter also referred to as “p layer 8n”) containing acceptor impurities is provided in contact with the p layer 4n. The first and second P-type body semiconductor layers form an N-type MOS transistor body (an example of an “N-type MOS transistor body” in the claims).

An n+ layer 7an, which is a second N-type impurity layer containing donor impurities at high concentrations (hereinafter semiconductor regions containing donor impurities at high concentrations are referred to as “n+ layer”) is provided on one side of the p layer 8n. An n+ layer 7bn, which is a third N-type impurity layer, is provided on the side opposite the n+ layer 7an.

A second N-type gate insulating layer 9n is disposed on the upper surface of the p layer 8n. The second N-type gate insulating layer 9n is positioned in contact with or in a close proximity to the n+ layers 7an and 7bn. A second N-type gate conductor layer 10n is disposed on the side opposite the second P-type body semiconductor layer 8n and is in contact with the second N-type gate insulating layer 9n.

In this manner, the N-type MOS transistor 30n is formed by the substrate 20, the first P-type semiconductor layer 1n, the first N-type insulating layer 2n, the first N-type gate insulating layer 5n, the first N-type gate conductor layer 22n, the second N-type insulating layer 6n, the first N-type impurity layer 3n, the first P-type body semiconductor layer 4n, the second N-type impurity layer 7an, the third N-type impurity layer 7bn, the second P-type body semiconductor layer 8n, the second N-type gate insulating layer 9n, and the second N-type gate conductor layer 10n. The n+ layer 7an of the N-type MOS transistor 30n is connected to an N-type source line Sn, the n+ layer 7bn to an N-type drain line Dn, and the second N-type gate conductor layer 10n to an N-type gate line Gn. The first N-type gate conductor layer 22n is connected to an N-type plate line PLn. The first N-type impurity layer 3n is connected to an N-type bottom line BTLn. By controlling the voltages of the N-type source line, the N-type drain line, the N-type gate line, the N-type plate line, and the N-type bottom line, an erase operation (an example of an “erase operation” in the claims) and a write operation (an example of a “write operation” in the claims) of the N-type MOS transistor 30n can be performed.

Next, the structure of the P-type MOS transistor 30p will be described. A first N-type semiconductor layer 1p (hereinafter also referred to as “n layer 1p”) is disposed on the substrate 20. The first N-type semiconductor layer 1p is composed of silicon containing donor impurities and exhibits n-type conductivity. A columnar first P-type impurity layer 3p (hereinafter also referred to as “p layer 3p”) containing acceptor impurities extends vertically from the surface of the n layer 1p. A columnar first N-type body semiconductor layer 4p (hereinafter also referred to as “n layer 4p”) containing donor impurities is disposed on the first P-type impurity layer 3p. A first P-type insulating layer 2p covers a portion of the n layer 1p and a portion of the p layer 3p. A first P-type gate insulating layer 5p covers a portion of the n layer 4p. A first P-type gate conductor layer 22p is disposed in contact with the first P-type insulating layer 2p and the first P-type gate insulating layer 5p. A second P-type insulating layer 6p is disposed in contact with the first P-type gate insulating layer 5p and the first P-type gate conductor layer 22p. A second N-type body semiconductor layer 8p (hereinafter also referred to as “n layer 8p”) containing donor impurities is provided in contact with the n layer 4p. The first and second N-type body semiconductor layers form a P-type MOS transistor body (an example of a “P-type MOS transistor body” in the claims).

A p⁺ layer 7ap, which is a second P-type impurity layer containing acceptor impurities at high concentrations (hereinafter semiconductor regions containing acceptor impurities at high concentrations are referred to as the “p⁺ layer”) is provided on one side of the n layer 8p. A p⁺ layer 7bp, which is a third P-type impurity layer, is provided on the side opposite the p⁺ layer 7ap.

The N-type MOS transistor 30n and the P-type MOS transistor 30p are isolated from each other by a first element separation film 11. Adjacent N-type MOS transistor 30n and adjacent P-type MOS transistor 30p are respectively isolated from each other by second element separation films 18n and 18p.

A second P-type gate insulating layer 9p is provided on the upper surface of the n layer 8p. The second P-type gate insulating layer 9p is positioned in contact with or in a close proximity to the p⁺ layers 7ap and 7bp. A second P-type gate conductor layer 10p is disposed on the side opposite the second N-type body semiconductor layer 8p and is in contact with the second P-type gate insulating layer 9p.

In this manner, the P-type MOS transistor 30p is formed by the substrate 20, the first N-type semiconductor layer 1p, the first P-type insulating layer 2p, the first P-type gate insulating layer 5p, the first P-type gate conductor layer 22p, the second P-type insulating layer 6p, the first P-type impurity layer 3p, the second N-type semiconductor layer 4p, the second P-type impurity layer 7ap, the third P-type impurity layer 7bp, the second N-type body semiconductor layer 8p, the second P-type gate insulating layer 9p, and the second P-type gate conductor layer 10p. The p⁺ layer 7ap of the P-type MOS transistor 30p is connected to a P-type source line Sp, the p⁺ layer 7bp to a P-type drain line Dp, and the second P-type gate conductor layer 10p to a P-type gate line Gp. The second P-type gate conductor layer 22p is connected to a P-type plate line Plp. The first P-type impurity layer 3p is connected to a P-type bottom line BTLp. By controlling the voltages of the P-type source line, the P-type drain line, the P-type gate line, the P-type plate line, and the P-type bottom line, the erase operation and the write operation of the P-type MOS transistor 30p can be performed.

In FIGS. 1A and 1B, the first N-type insulating layer 2n and the first P-type insulating layer 2p may be constructed in the same process step; the first N-type gate insulating layer 5n and the first P-type gate insulating layer 5p may be constructed in the same process step; the first N-type gate conductor layer 22n and the first P-type gate conductor layer 22p may be constructed in the same process step; the second N-type insulating layer 6n and the second P-type insulating layer 6p may be constructed in the same process step; the second N-type gate insulating layer 9n and the second P-type gate insulating layer 9p may be constructed in the same process step; and the second N-type gate conductor layer 10n and the second P-type gate conductor layer 10p may be constructed in the same process step.

With reference to FIG. 2, first, the carrier behavior in the write operation of the N-type MOS transistor 30n according to the first embodiment of the present invention will be described. In the following description, the majority carriers in the n⁺ layer 7an and the n⁺ layer 7bn are electrons; for example, p⁺ poly (hereinafter poly Si containing acceptor impurities at high concentrations is referred to as “p⁺ poly”) is used for the first N-type gate conductor layer 22n connected to PLn; n⁺ poly (hereinafter poly Si containing donor impurities at high concentrations is referred to as “n⁺ poly”) is used for the second N-type gate conductor layer 10n connected to the N-type gate line Gn; and the second P-type body semiconductor layer 8n is used as a P-type semiconductor layer constituting the body of the N-type MOS transistor 30n. As illustrated in FIG. 2, the N-type MOS transistor 30n is designed to operate with specific configuration elements: the n⁺ layer 7an as the source, the n⁺ layer 7bn as the drain, the gate insulating layer 9n, the gate conductor layer 10n as the gate, and the second P-type body semiconductor layer 8n as the substrate. For example, 0 V is applied to the p layer 1n, 0 V is input to the n⁺ layer 7an connected to the source line Sn, 3 V is input to the n⁺ layer 7bn connected to the drain line Dn, 0 V is input to the gate conductor layer 22n connected to the plate line PLn, and 1.5 V is input to the gate conductor layer 10n connected to the gate line Gn. A partial inversion layer 12 is formed beneath the gate insulating layer 9n, which is positioned under the gate conductor layer 10n, and a pinch-off point 14 is formed. Consequently, the N-type MOS transistor 30n having the gate conductor layer 10n operates in the saturation region.

As a result, in the N-type MOS transistor 30n having the gate conductor layer 10n, the electric field is maximized between the pinch-off point 14 and the n⁺ layer 7bn. In this region, an impact ionization phenomenon occurs. Due to this impact ionization phenomenon, electrons accelerated from the n⁺ layer 7an, which is connected to the source line Sn, toward the n⁺ layer 7bn, which is connected to the drain line Dn, collide with the Si lattice. The kinetic energy involved in this collision generates electron-hole pairs. Some of the electrons from the generated pairs flow into the gate conductor layer 10n, while most of the electrons flow into the n⁺ layer 7bn, which is connected to the drain line Dn. As a result, a hole group 13 is formed in the second P-type body semiconductor layer 8n.

Instead of causing the impact ionization phenomenon described above, a gate-induced drain leak (GIDL) current may be applied to generate the hole group 13 (see, for example, E. Yoshida, T. Tanaka, “A Capacitorless 1T-DARM Technology Using Gate-Induced Drain-Leakage (GIDL) Current for Low-Power and High-Speed Embedded Memory,” IEEE Trans, on Electron Devices vol. 53, pp. 692-697 (2006)).

The hole group 13 serves as the majority carriers in the p layer 4n and the p layer 8n. The holes in the hole group 13 move to the p layer 4n due to the concentration gradient and accumulate throughout the p layer 4n and the p layer 8n in a short period of time. Consequently, the p layer 8n, which serves as the substrate of the N-type MOS transistor 30n having the gate conductor layer 10n, can be regarded as being positively charged in the non-equilibrium state. The holes in the depletion layer also move toward the source Sn or the n layer 3n through the electric fields and recombine with electrons. As a result, the threshold voltage of the N-type MOS transistor 30n having the gate conductor layer 10n is decreased because the substrate is positively charged due to holes temporarily accumulating in the p layer 4n and the p layer 8n. Consequently, as illustrated in FIG. 3, the threshold voltage of the N-type MOS transistor 30n having the gate conductor layer 10n connected to the gate line Gn is decreased. This state is designed as a write operation state of the N-type MOS transistor 30n.

After the write operation, the positive threshold voltage (an example of a “positive threshold voltage” in the claims) of the N-type MOS transistor 30n is smaller than the difference between the supply voltage and the ground voltage. Here, a supply voltage Vcc is, for example, 1.0 V, and a ground voltage Vss is, for example, 0 V. Therefore, the difference is 1.0 V. Accordingly, the positive threshold voltage is smaller than or equal to 1.0 V.

With reference to FIG. 2, second, the carrier behavior in the write operation of the P-type MOS transistor 30p according to the first embodiment of the present invention will be described. In the following description, the majority carriers in the p⁺ layer 7ap and the p⁺ layer 7bp are holes; for example, p⁺ poly (hereinafter poly Si containing acceptor impurities at high concentrations is referred to as “p⁺ poly”) is used for the gate conductor layer 22n connected to PLp; n⁺ poly (hereinafter poly Si containing donor impurities at high concentrations is referred to as “n⁺ poly”) is used for the gate conductor layer 10p connected to the gate line Gp; and the second N-type body semiconductor layer 8p is used as a N-type semiconductor layer constituting the body of the P-type MOS transistor 30p. As illustrated in FIG. 2, the P-type MOS transistor 30p is designed to operate with specific configuration elements: the p⁺ layer 7ap as the source, the p⁺ layer 7bp as the drain, the gate insulating layer 9p, the gate conductor layer 10p as the gate, and the second N-type body semiconductor layer 8p as the substrate. For example, 0 V is applied to the n layer 1p, 3 V is input to the p⁺ layer 7ap connected to the source line Sp, 0 V is input to the p⁺ layer 7bp connected to the drain line Dp, 0 V is input to the gate conductor layer 22p connected to the plate line PLp, and 1.5 V is input to the gate conductor layer 10p connected to the gate line Gp. A partial inversion layer 15 is formed beneath the gate insulating layer 9p, which is positioned under the gate conductor layer 10p, and a pinch-off point 17 is formed. Consequently, the P-type MOS transistor 30p having the gate conductor layer 10p operates in the saturation region.

As a result, in the P-type MOS transistor 30p having the gate conductor layer 10p, the electric field is maximized between the pinch-off point 17 and the p⁺ layer 7bp. In this region, an impact ionization phenomenon occurs. Due to this impact ionization phenomenon, holes accelerated from the p⁺ layer 7ap, which is connected to the source line Sp, toward the p⁺ layer 7bp, which is connected to the drain line Dp, collide with the Si lattice. The kinetic energy involved in this collision generates electron-hole pairs. Some of the holes from the generated pairs flow into the gate conductor layer 10p, while most of the holes flow into the p⁺ layer 7bp, which is connected to the drain line Dp. As a result, an electron group 16 is formed in the second N-type body semiconductor layer 8p.

Instead of causing the impact ionization phenomenon described above, a gate-induced drain leak (GIDL) current may be applied to generate the electron group 16 (see, for example, E. Yoshida, T. Tanaka, “A Capacitorless 1T-DARM Technology Using Gate-Induced Drain-Leakage (GIDL) Current for Low-Power and High-Speed Embedded Memory,” IEEE Trans, on Electron Devices vol. 53, pp. 692-697 (2006)).

The electron group 16 serves as the majority carriers in the n layer 4p and the n layer 8p. The electrons in the electron group 16 move to the n layer 4p due to the concentration gradient and accumulate throughout the n layer 4p and the n layer 8p in a short period of time. Consequently, the n layer 8p, which serves as the substrate of the P-type MOS transistor 30p having the gate conductor layer 10p, can be regarded as being negatively charged in the non-equilibrium state. The electrons in the depletion layer also move toward the source Sp or the p layer 3p through the electric fields and recombine with holes. As a result, the threshold voltage of the P-type MOS transistor 30p having the gate conductor layer 10p is increased because the substrate is negatively charged due to electrons temporarily accumulating in the n layer 4p and the n layer 8p. Consequently, as illustrated in FIG. 3, the threshold voltage of the P-type MOS transistor 30p having the gate conductor layer 10p connected to the gate line Gp is increased. This state is designed as a write operation state of the P-type MOS transistor 30p.

After the write operation, the absolute value of the negative threshold voltage (an example of a “negative threshold voltage” in the claims) of the P-type MOS transistor 30p is smaller than the difference between the supply voltage and the ground voltage. Here, a supply voltage Vcc is, for example, 1.0 V, and a ground voltage Vss is, for example, 0 V. Therefore, the difference is 1.0 V. Accordingly, the absolute value of the negative threshold voltage is smaller than or equal to 1.0 V.

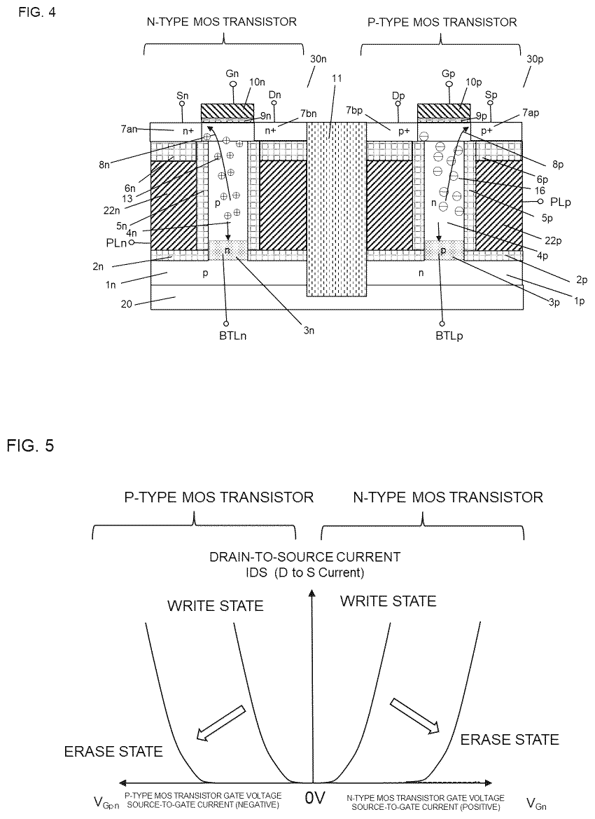

Next, with reference to FIGS. 4 and 5, the erase operation mechanism of the N-type MOS transistor 30n and the P-type MOS transistor 30p will be described. First, the erase operation of the N-type MOS transistor 30n will be described. Before the erase operation in FIG. 4, the hole group 13 formed through impact ionization during the write operation in the previous cycle accumulates in the p layer 4n and the p layer 8n. As illustrated in FIG. 4, during the erase operation, the source line Sn is set to a negative voltage VERAn, where VERAn is, for example, −1 V. As a result, regardless of the initial potential of the p layer 8n, the PN junction between the n⁺ layer 7an, which is connected to the source line Sn and serves as the source, and the p layer 8n becomes forward biased. As a result, the hole group 13 formed through impact ionization in the previous cycle and accumulating in the p layer 4n and the p layer 8n are moved to the n⁺ layer 7an connected to the source line Sn. Some holes flow from the p layer 4n to the n layer 3n and recombine with electrons, albeit in small amounts. As a result, the hole concentration in the p layer 4n and the p layer 8n decreases over time, and the positive threshold voltage of the N-type MOS transistor 30n having the gate conductor layer 10n connected to the gate line Gn increases as illustrated in FIG. 5. Here, the positive threshold voltage of the N-type MOS transistor 30n after erasing is, for example, 1.3 V. This is greater than the difference between the supply voltage Vcc (1.0 V) and the ground voltage (0 V), which is specifically 1.0 V.

Next, with reference to FIGS. 4 and 5, the erase operation of the P-type MOS transistor 30p will be described. Before the erase operation in FIG. 4, the electron group 16 formed through impact ionization during the write operation in the previous cycle accumulates in the n layer 4p and the n layer 8p. As illustrated in FIG. 4, during the erase operation, the source line Sp is set to a positive voltage VERAp, where VERAp is, for example, +3 V. As a result, regardless of the initial potential of the n layer 8p, the PN junction between the p⁺ layer 7ap, which is connected to the source line Sp and serves as the source, and the n layer 8p becomes forward biased. As a result, the electron group 16 formed through impact ionization in the previous cycle and accumulating in the n layer 4p and the n layer 8p are moved to the p⁺ layer 7ap connected to the source line Sp. Some electrons flow from the n layer 4p to the p layer 3p and recombine with holes, albeit in small amounts. As a result, the electron concentration in the n layer 4p and the n layer 8p decreases over time, and the negative threshold voltage of the P-type MOS transistor 30p having the gate conductor layer 10p connected to the gate line Gp decreases to a level lower than the level during the write operation, as illustrated in FIG. 5. Here, the absolute value of the negative threshold voltage of the P-type MOS transistor 30p after erasing is, for example, 1.3 V. This is greater than the difference between the supply voltage Vcc (1.0 V) and the ground voltage (0 V), which is specifically 1.0 V.

In the semiconductor device of an embodiment of the present invention, a single logic circuit (an example of a “logic circuit” in the claims) constituted by the N-type MOS transistor 30n and the P-type MOS transistor 30p described above is disposed on the substrate 20, or multiple logic circuits each constituted by the N-type MOS transistor 30n and the P-type MOS transistor 30p described above are disposed in a two-dimensional layout on the substrate 20.

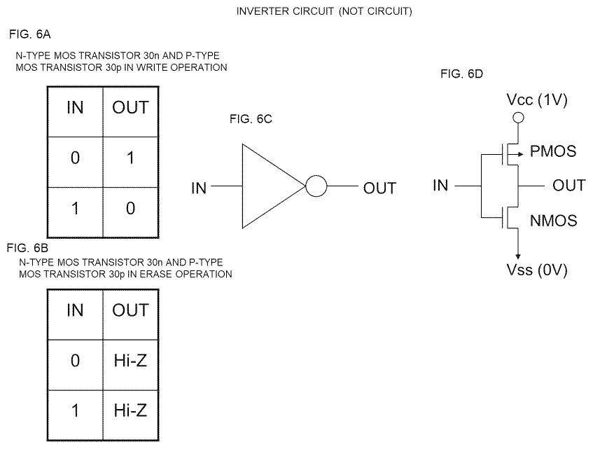

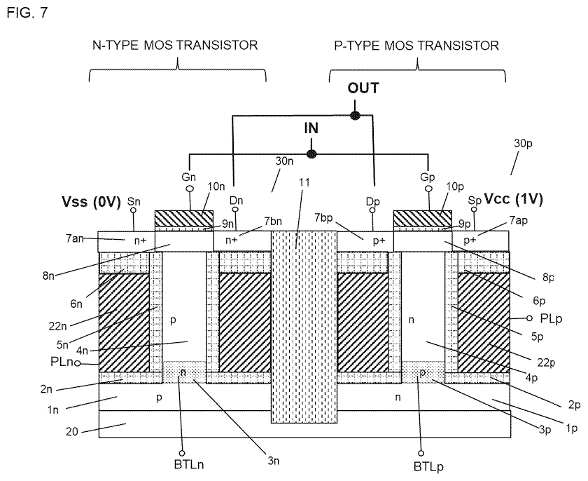

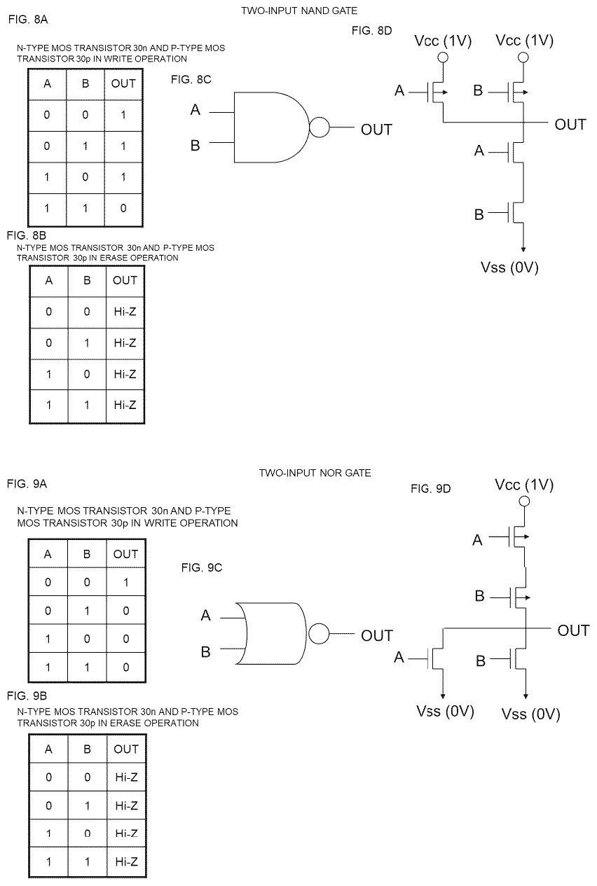

An example of the logic circuit according to an embodiment of the present invention will be described with reference to FIGS. 6A, 6B, 6C, 6D, 7, 8A, 8B, 8C, 8D, 9A, 9B, 9C, and 9D. FIGS. 6A, 6B, 6C, and 6D illustrate an inverter circuit. FIG. 7 illustrates a sectional view of the structure of the inverter circuit. FIGS. 8A, 8B, 8C, and 8D illustrate a two-input NAND gate circuit having input signals A and B. FIGS. 9A, 9B, 9C, and 9D illustrate a two-input NOR gate circuit having input signals A and B.

The inverter circuit of an embodiment of the present invention will be described with reference to FIGS. 6A, 6B, 6C, 6D, and 7. The source Sn of the N-type MOS transistor 30n is coupled to the ground voltage Vss, and the source Sp of the P-type MOS transistor 30p is coupled to the supply voltage Vcc. Here, it is assumed that the ground voltage Vss is, for example, 0 V, and the supply voltage Vcc is, for example, 1V. The drain Dn of the N-type MOS transistor 30n and the drain Dp of the P-type MOS transistor 30p are coupled to an output OUT. The gate Gn of the N-type MOS transistor 30n and the gate Gp of the P-type MOS transistor 30p are coupled to an input IN. While the N-type MOS transistor 30n and the P-type MOS transistor 30p are in the write operation state, the absolute values of the threshold voltages of the N-type MOS transistor 30n and the P-type MOS transistor 30p are smaller than the difference between the supply voltage Vcc and the ground voltage Vss, which is specifically 1.0 V. As a result, the output OUT (which is an example of the “output” in the claims) of the inverter circuit is in a low impedance state (which is an example of a “low impedance state” in the claims) and outputs either a logic “1” (which is an example of a “logic “1” in the claims) or a logic “0” (which is an example of a “logic “0” in the claims), according to a truth table illustrated in FIG. 6A.

By contrast, while the N-type MOS transistor 30n and the P-type MOS transistor 30p are in an erase operation state, the absolute values of the threshold voltages of the N-type MOS transistor 30n and the P-type MOS transistor 30p are greater than the difference between the supply voltage Vcc and the ground voltage Vss, which is specifically 1.0 V. As a result, the output OUT of the inverter circuit is in a high impedance state (an example of a “high impedance state” in the claims). The output OUT is thus in the high impedance state (Hi-Z state) in the erase operation state, according to a truth table illustrated in FIG. 6B.

FIGS. 8A, 8B, 8C, and 8D illustrate an exemplary logic circuit of a two-input NAND gate circuit having two kinds of input signals A and B. FIGS. 9A, 9B, 9C, and 9D illustrate an exemplary logic circuit of a two-input NOR gate circuit having two kinds of input signals A and B. Also in these logic circuits, while the N-type MOS transistor 30n and the P-type MOS transistor 30p are in the write operation state, the output OUT is in the low impedance state. According to truth tables in FIGS. 8A and 9A, either a logic “1” or logic “0” is output based on the input IN. While the N-type MOS transistor 30n and the P-type MOS transistor 30p are in the erase operation state, the output OUT is in the high impedance state. According to truth tables illustrated in FIGS. 8B and 9B, the output OUT is in the high impedance state (Hi-Z state) in the erase operation state.

The present embodiment has the following feature:

### Feature 1

A low-power consumption field programmable gate array (FPGA) can be easily implemented using the logic circuit constituted by the N-type MOS transistor 30n and the P-type MOS transistor 30p according to the first embodiment of the present invention. The logic circuit realizes reconfigurable logics where logic circuit configurations can be changed during operation of the semiconductor device. The applications of the logic circuit range broadly; particularly, the logic circuit can be used in memory-logic integrated circuits. In the logic circuit constituted by the N-type MOS transistor 30n and the P-type MOS transistor 30p of an embodiment of the present invention, a portion of the hole group 13 and a portion of the electron group 16, which are the majority carriers in the semiconductor layers 4n and 4p during the write operation, move from the second P-type semiconductor layer 4n and the second N-type semiconductor layer 4p to the second P-type body semiconductor layer 8n and the second N-type body semiconductor layer 8p. As a result, when the N-type MOS transistor 30n and the P-type MOS transistor 30p are miniaturized, this configuration facilitates the accumulation of the hole group 13 in the second P-type body semiconductor layer 8n and the accumulation of the electron group 16 in the second N-type body semiconductor layer 8p. The threshold voltage of the N-type MOS transistor 30n and the threshold voltage of the P-type MOS transistor 30p can be controlled based on the concentration of the hole group 13 in the second P-type body semiconductor layer 8n and the concentration of the electron group 16 in the second N-type body semiconductor layer 8p. This configuration enables the implementation of miniaturized, highly-integrated MOS transistors such as FinFETs, nanosheets, and GAA transistors. Therefore, semiconductor devices with variable logic circuits capable of ultra-high integration can be provided at low cost.

The present invention may be embodied in various other embodiments and modifications without departing from the broader spirit and scope of the present invention. The embodiment described above is intended to illustrate practical examples of the present invention, not to limit the scope of the present invention. The above practical examples and modifications can be combined in any manner. Modes formed by removing one or some of the configurational features of the embodiment, as needed, also fall within the scope of the technical idea of the present invention.

The semiconductor device using the logic circuit constituted by N-type and P-type MOS transistors according to the present invention implements variable logic circuits that can be more easily altered during operation.

What is claimed is:

1. A semiconductor device comprising:
a substrate; and
an N-type MOS transistor and a P-type MOS transistor that are disposed on the substrate, the N-type MOS transistor including an N-type MOS transistor body, an N-type gate conductor layer, and an N-type insulating layer, the P-type MOS transistor including a P-type MOS transistor body, a P-type gate conductor layer, and a P-type insulating layer, wherein
the N-type MOS transistor body is constituted by a first P-type body semiconductor layer configured to accumulate a hole group and a second P-type body semiconductor layer connected to the first P-type body semiconductor layer and configured to control a positive threshold voltage of the N-type MOS transistor based on concentration of the hole group in the first P-type body semiconductor layer,
the P-type MOS transistor body is constituted by a first N-type body semiconductor layer configured to accumulate an electron group and a second N-type body semiconductor layer connected to the first N-type body semiconductor layer and configured to control a negative threshold voltage of the P-type MOS transistor based on concentration of the electron group in the first N-type body semiconductor layer,
the N-type gate conductor layer and the P-type gate conductor layer are composed of the same material,
the N-type insulating layer is disposed between the second P-type body semiconductor layer and the N-type gate conductor layer, the P-type insulating layer is disposed between the second N-type body semiconductor layer and the P-type gate conductor layer, and the N-type insulating layer and the P-type insulating layer are composed of the same material,
the semiconductor device is configured to perform
an erase operation by increasing the positive threshold voltage of the N-type MOS transistor and decreasing the negative threshold voltage of the P-type MOS transistor, the increasing the positive threshold voltage of the N-type MOS transistor being achieved by decreasing the hole group in the first P-type body semiconductor layer and the hole group in the second P-type body semiconductor layer within the N-type MOS transistor, the decreasing the negative threshold voltage of the P-type MOS transistor being achieved by decreasing the electron group in the first N-type body semiconductor layer and the electron group in the second N-type body semiconductor layer within the P-type MOS transistor, and
a write operation by decreasing the positive threshold voltage of the N-type MOS transistor and increasing the negative threshold voltage of the P-type MOS transistor, the decreasing the positive threshold voltage of the N-type MOS transistor being achieved by increasing the hole group in the first P-type body semiconductor layer and the hole group in the second P-type body semiconductor layer within the N-type MOS transistor, the increasing the negative threshold voltage of the P-type MOS transistor being achieved by increasing the electron group in the first N-type body semiconductor layer and the electron group in the second N-type body semiconductor layer within the P-type MOS transistor, and
the N-type MOS transistor and the P-type MOS transistor forms a logic circuit configured to provide an output in a high impedance state (Hi-Z state) during the erase operation and to provide an output of a logic “1” or a logic “0” in a low impedance state during the write operation.

2. The semiconductor device according to claim 1, wherein
during the erase operation, in the N-type MOS transistor, a portion of the hole groups remaining in the first P-type body semiconductor layer and the second P-type body semiconductor layer is removed by recoupling the portion of the hole groups with an electron group in at least one first N-type impurity layer that is disposed in contact with the first P-type body semiconductor layer or the second P-type body semiconductor layer,
during the erase operation, in the P-type MOS transistor, a portion of the electron groups remaining in the first N-type body semiconductor layer and the second N-type body semiconductor layer is removed by recoupling the portion of the electron groups with a hole group in at least one first P-type impurity layer that is disposed in contact with the first N-type body semiconductor layer or the second N-type body semiconductor layer,
during the write operation, in the N-type MOS transistor, the hole group in the first P-type body semiconductor layer and the hole group in the second P-type body semiconductor layer are formed through an impact ionization phenomenon caused by a current flowing between a second N-type impurity layer and a third N-type impurity layer that are disposed in contact with the first P-type body semiconductor layer or the second P-type body semiconductor layer, or the hole group in the first P-type body semiconductor layer and the hole group in the second P-type body semiconductor layer are formed by a gate-induced drain leak current,
the semiconductor device is configured to perform an operation that causes a portion or all of the hole groups in the first P-type body semiconductor layer and the second P-type body semiconductor layer to remain in the first P-type body semiconductor layer and the second P-type body semiconductor layer,
during the write operation, in the P-type MOS transistor, the electron group in the first N-type body semiconductor layer and the electron group in the second N-type body semiconductor layer are formed through an impact ionization phenomenon caused by a current flowing between a second P-type impurity layer and a third P-type impurity layer that are disposed in contact with the first N-type body semiconductor layer or the second N-type body semiconductor layer, or the electron group in the first N-type body semiconductor layer and the electron group in the second N-type body semiconductor layer are formed by a gate-induced drain leak current, and
the semiconductor device is configured to perform
an operation that causes a portion or all of the electron groups in the first N-type body semiconductor layer and the second N-type body semiconductor layer to remain in the first N-type body semiconductor layer and the second N-type body semiconductor layer.

3. The semiconductor device according to claim 2, wherein the second N-type impurity layer is connected to an N-type source line in the N-type MOS transistor, and the third N-type impurity layer is connected to an N-type drain line in the N-type MOS transistor.

4. The semiconductor device according to claim 2, wherein the second P-type impurity layer is connected to a P-type source line in the P-type MOS transistor, and the third P-type impurity layer is connected to a P-type drain line in the P-type MOS transistor.

5. The semiconductor device according to claim 1, wherein the logic circuit is an inverter circuit, a NAND gate circuit, or a NOR gate circuit.

6. The semiconductor device according to claim 1, wherein the first N-type body semiconductor layer and the second N-type body semiconductor layer are provided as an N-type well in a P-type semiconductor layer.

7. The semiconductor device according to claim 1, wherein the first P-type body semiconductor layer and the second P-type body semiconductor layer are provided as a P-type well in an N-type semiconductor layer.

8. The semiconductor device according to claim 1, wherein
each of the positive threshold voltage of the N-type MOS transistor and an absolute value of the negative threshold voltage of the P-type MOS transistor is
smaller than a difference between a supply voltage to the logic circuit and a ground voltage in the write operation, and
greater than the difference between the supply voltage to the logic circuit and the ground voltage in the erase operation.

9. The semiconductor device according to claim 1, wherein the hole groups in the first P-type body semiconductor layer and the second P-type body semiconductor layer are moved by a diffusion current.

10. The semiconductor device according to claim 1, wherein the electron groups in the first N-type body semiconductor layer and the second N-type body semiconductor layer are moved by a diffusion current.
